(19) United States
(12) Patent Application Publication
(10) Pub. No.: US 2010/0009095 A1
(43) Pub. Date: Jan. 14, 2010

(54) Method and Apparatus for Producing a Coating on a Substrate

(75) Inventors: Luke John Ward, Selby N Yorks (GB); Jas Pal Singh Badyal, County Durham (GB)

Correspondence Address: HEAD, JOHNSON & KACHIGIAN, 228 W 17TH PLACE, TULSA, OK, 74119, US

(73) Assignees: SURFACE INNOVATIONS LTD., Wolsingham, County Durham (GB); UNIVERSITY OF DURHAM, Durham (GB)

(21) Appl. No.: 12/085,000

(22) PCT Filed: Mar. 3, 2006
(86) PCT No.: PCT/GB2006/000763

§ 371 Date: Sep. 17, 2009

(30) Foreign Application Priority Data
Mar. 3, 2005 (GB) 0504384.9

(51) Int. Cl. C23C 16/448; C23C 16/00; B05D 7/24

(52) U.S. Cl. 427/569; 118/723 R

(57) ABSTRACT

The invention is directed toward the use of an atomizer to inject a coating material typically in the form of a liquid/solid particulate slurry into a sub-atmospheric pressure plasma to generate a high flux of excited coating forming material that permits the rapid deposition of a composite coating onto a substrate. The use of plasma discharges at reduced pressures results in the more efficient consumption of process precursors and gases, a reduced risk of explosion compared to atmospheric pressure processes and facilitates the removal of volatile components from the deposited composite coatings prior to their use.

### CROSS-REFERENCES TO RELATED APPLICATIONS

This application is the US National Phase of PCT Application No. GB2006/000763 filed 3 Mar. 2006 which claims priority from British Patent Application No. 0504384.9 filed 3 Mar. 2005.

### STATEMENT REGARDING FEDERALLY SPONSORED RESEARCH AGREEMENT

Not Applicable

### THE NAMES OF THE PARTIES TO A JOINT RESEARCH AGREEMENT

Not Applicable

### INCORPORATION-BY-REFERENCES OF MATERIAL SUBMITTED ON A COMPACT DISC

Not Applicable

### BACKGROUND OF THE INVENTION

1. Field of the Invention

This invention relates to a method for producing a coating such as a composite film by plasma deposition at subatmospheric pressures.

2. Description of the Related Art

Composite coatings are heterogeneous materials that comprise small particles (typically nmmm diameter) dispersed within a continuous matrix that is composed of a different, often polymeric, material. The incorporation of particles within a coating can confer a number of important benefits that depend on factors such as the nature of the particles, their concentration, and their interaction with the matrix. A novel single-step methodology for producing such composite films is hence a useful and innovative addition to the art.

Examples of benefits that can accrue to an article as a consequence of particulate material incorporated within an applied composite coating include, but are not restricted to, vapor sensing ability, wear resistance, energy production and storage, heat reflectance, light reflectance, electrical and thermal conductivity, photo-catalytic self-cleaning, biological activity, nano-filtration, controlled release, opto-electronic functionality, liquid or stain resistance, lubricity, and magnetic properties.

It is known to use a means of monomer atomization (typically an ultrasonic nozzle) to deposit coatings derived from a liquid containing no particulate material. Patent WO98 10116 (Ultrasonic Nozzle Reed For Plasma Deposited Networks, Talison Research) includes the use of continuous plasma to create cross-linked polymeric coatings from an atomized precursor within a chemical vapor deposition reactor.

Patent WO0228548 (Method and Apparatus for Forming a Coating, Dow Corning) utilizes atmospheric-pressure plasmas in conjunction with an altrasonic nozzle to deposit coatings.

The potential use of solid coating forming materials is cited. However, the exclusive use of atmospheric-pressure plasmas has a number of significant disadvantages. There include the risk of a number of significant disadvantages. These include the risk of explosion and the contamination of personnel and equipment during production, the inefficient use of process materials (the cited plasma system uses large quantities of helium) and a product that contains quantities of unadhered material. This poorly bonded material could migrate to the coating surface; compromising the stability of interfacial properties and contaminating the environment during normal use.

The aim of the present invention is to provide an improved method and sapparatus for the application of composite coatings on substrates.

### BRIEF SUMMARY OF THE INVENTION

In a first aspect of the invention there is provided a method for depositing a composite coating onto a substrate, said method comprising the introduction of a coating material to form the coating on at least part of the substrate and wherein the coating material is introduced in the form of an atomized solid/liquid slurry into a sub-atmospheric pressure plasma prior to and/or when contacting the substrate.

Typically, the plasma is a continuous non-equilibrium sub atmospheric pressure plasma.

The application of a subatmospheric pressure plasma to the atomised droplets of slurry creates reactive reactive species such as ions, radicals and metastable molecules. Droplets of coating forming material containing these species are subsequently deposited onto the substrate where they yield a coating containing solid particles dispersed within a substantially continuous matrix.

Further excitation of the coating forming material may also occur after its adsorption onto the substrate.

The liquid fraction of the solid/liquid coating forming slurry employed in the invention contains one or more components that, upon atomisation and exposure to a subatmospheric pressure plasma discharge, are capable of being transformed into the continuous phase of the desired composite coating.

Particularly suitable materials in this respect include, but are not restricted to, organic monomers that, after atomization and excitation, are capable of forming a continuous polymer matrix. Other suitable coating materials include liquid organo-metallic, organo-silicon and inorganic compounds that are capable of yielding continuous organo-metallic, organo-silicon or inorganic matrices.

The solid content of the solid/liquid slurry employed in the invention typically comprises particles with diameters in the nm to mm range. The upper particle-size limit being in part determined by the utilized means of atomisation. Solid materials suitable for inclusion within a composite coating forming liquid/solid slurry include, but are not limited to, organic, inorganic, organo-metallic, metallic, organo-silicon, and bioactive particles.

Specific examples of particulate materials that can be dispersed throughout the continuous phase of composite coatings include titanium dioxide (photo-catalytic functionality), manganese-oxides (super-paramagnetic functionality), silver (optical absorption properties, heat reflective properties, anti-bacterial properties), carbon-black (for gas absorption and sensing), carbon-fibers (wear resistance), graphite and/or microfine PTFE (lubricity), palladium/gold (organic solvent sensing) and organic light emitting molecules e.g. tris(8-quinolinolato) aluminium III (for use within organic light-emitting devices).

The particulate solid component may be surface modified prior to its inclusion within the liquid/solid coating forming slurry.

In one embodiment, the particles are subject to a treatment that enhances their dispersion within the liquid coating-forming material. This prevents agglomeration and precipitation of the solid component of the slurry prior to its introduction into the sub-atmospheric pressure plasma and improves particle dispersion within the resulting composite coating. Examples of particles that have been surface modified for enhanced dispersion include C16-silane modified silica nanoparticles (aerosil R816, DeGussa); the water-repellent surface coating improves particle dispersion within hydrophobic coating forming materials such as perfluoroacrylate monomers.

In another embodiment, prior to their inclusion within the coating forming slurry, the particles are subjected to a surface-modification pre-treatment that enhances their adhesion to the continuous phase eventually formed from the liquid component of the coating forming material. Examples of particles that have been surface modified for enhanced adhesion include methacrylsilane modified silica nano-particles (aerosil R711, DeGussa) that on activation can form covalent linkages with the liquid coating-forming material. The enhanced bonding between the particulate and continuous phases of the composite that results from this pretreatment improves the physical properties of the coating obtained.

The use of an atomizer in the method is beneficial in that it enables rapid deposition rates to be achieved even when the liquid component of the solid/liquid slurry possesses a low vapor pressure. This is in contrast to traditional plasma methods that require gaseous or highly volatile precursor materials.

In a preferred embodiment, the atomizer is an ultrasonic nozzle supplied with coating forming material in the form of a liquid/solid slurry. Suitable ultrasonic nozzle atomizers are manufactured by Sono-tek Corp.

In another embodiment, the atomizer is a nebulizer supplied with coating forming material in the form of a liquid/solid slurry, and a carrier gas which may be inert or reactive.

The liquid/solid slurry coating forming material may be conveyed from its reservoir to the atomizer by virtue of gravitational potential and/or the pressure differential between the reservoir and the sub-atmospheric pressure plasma chamber.

In one embodiment, the pressure differential between the chamber and the slurry reservoir is augmented by the application of a positive pressure of an inert gas within the reservoir, above the pressure level of the liquid/solid coating forming material.

In another embodiment, the reservoir is in the form of a syringe and the pressure differential between the reservoir and the deposition chamber can be augmented by the use of a syringe pump.

More than one atomizer can be used to supply coating forming material to the subatmospheric pressure plasma. Within continuous coating apparatuses (especially within reel-to-reel apparatuses) these atomizing nozzles may be in an array distributed generally transverse to the direction of the moving substrate web. The number of atomizers and their spacing being such as to enable a sufficiently even distribution of composite-coating forming material over the entire width of the web.

Materials additional to the atomized liquid/solid slurry may also be included within the process.

In one embodiment, the additive materials are inert and act as buffers (suitable examples include the noble gases). A buffer may be necessary to maintain a required process pressure and/or carry the atomized coating forming material into an appropriate region of the deposition apparatus.

In another embodiment, the additive materials have the additional capacity to modify and/or be incorporated into the coating forming material and/or the resultant coating.

Suitable examples include reactive gases such as oxygen and ammonia.

In one embodiment, the introduction of materials additional to the atomized coating forming material is pulsed.

In one embodiment, the non-equilibrium sub-atmospheric pressure plasma discharge is generated by an alternating current voltage.

In another embodiment, the sub-atmospheric pressure plasma is produced by audiofrequencies, radio-frequencies or microwave-frequencies.

In its preferred embodiment the non-equilibrium sub-atmospheric pressure plasma is a radiofrequency glow discharge wherein the gas pressure may be 0.01 to 999 mbar and the applied average power is, for example, between 0.1 W and 10,000 W. Of particular utility for the method are low-pressure radiofrequency glow discharges that are operated at pressures between 0.01 and 10 mbar. However, any type of plasma capable of operation at a pressure of less than 1 atmosphere (1 atmosphere=1.01×105 Nm-2) may be deemed suitable if its use provides the benefits previously cited i.e. a reduced risk of explosion, the reduced risk of contaminating production personnel and equipment (by virtue of the containment of process materials within the chamber), and the removal of unadhered material from the product coatings.

In a yet further embodiment, the non-equilibrium sub-atmospheric pressure plasma is produced by direct current voltage.

The substrate to which the coating material is applied is located substantially inside the exciting medium during coating deposition.

In a further aspect of the invention, there is provided a method of producing a multilayered composite coating on a substrate wherein the substrate is repeatedly exposed to activated coating forming material produced as herein described.

In one embodiment, the composition of the liquid/solid precursor mixture and/or the nature of the sub-atmospheric pressure plasma are changed during the coating formation procedure.

In one embodiment, the substrate is coated continuously by use of a reel-to-reel apparatus.

In one embodiment, the composite coating formed on the substrate can be post-treated by exposure to further exciting media after deposition and/or pre-treated prior to coating by exposure to exciting media prior to coating deposition.

In one embodiment, the apparatus surrounding the sub-atmospheric pressure plasma region is heated to prevent condensation of coating forming material onto the chamber walls.

The substrate can comprise, but is not limited to: metal, glass, semiconductor, ceramic, polymer, woven or non-woven fibers, natural fibers, synthetic fibers, cellulosic material, and powder.

The coating forming material can constitute, but is not limited to, a mixture of organic, organosilicon, organometallic, or inorganic liquid coating precursor with a suspension of largely insoluble organic, organosilicon, organometallic, inorganic, or bioactive particles.

The composite coating can be selected to improve the hydrophobic and/or oleophobic, adhesive, gas barrier, wear resistance, moisture barrier, release, electrical and thermal conductivity, electrical and thermal reflectance, energy production and storage, filtration, magnetic, dielectric, bioactive, optical or tribological properties of the substrate.

After deposition of the composite film by the methods described herein the coated substrate may be subject to subsequent derivatization by methods known in the art (e.g. tethering of biomolecules).

In a further aspect of the invention, there is provided a method for depositing a composite coating formed from a liquid mixed with substantially insoluble particles (a liquid/solid slurry).

Said method comprising atomizing or nebulizing the coating forming material and introducing it into a sub-atmospheric pressure plasma that facilitates the formation of activated precursor species to the coating (such as monomeric or oligomeric radicals and ions) within the atomized droplets and/or upon their adsorption onto the substrate. The activated precursor species thence form a coating upon the substrate that contains solid particles within a matrix formed by the deposition of the excited liquid component.

In a preferred embodiment of the method, the coating forming material, a liquid/solid slurry, is atomized by an ultrasonic nozzle into a sub-atmospheric pressure plasma region, heated to prevent condensation. Other means of atomizing the coating forming material include, but are not limited to, nebulizers.

In one embodiment, the sub-atmospheric pressure plasma contains the atomized coating forming slurry material in the absence of other materials. In another embodiment of the invention, the atomized coating forming material is mixed with, for example, an inert or reactive gas. The additional material may be introduced into, prior to, or subsequent to the plasma chamber continuously or in a pulsed manner by way of, for example, a gas pulsing valve.

In a further aspect of the invention, there is provided an apparatus for the application of a composite coating to a substrate, said apparatus comprising a vacuum chamber, atomizing means for introducing an atomized coating forming slurry material into the chamber, means for creating a sub-atmospheric pressure plasma within the chamber, and a means for introducing and holding a substrate to be coated in the chamber. In the preferred embodiment, the aforementioned atomizing means directs the atomized coating forming material so that it passes through the sub-atmospheric pressure plasma prior to reaching the substrate.

In a preferred embodiment of the method, the sub-atmospheric pressure plasma is a low-pressure glow-discharge generated by the application of radiofrequencies at 13.56 MHz. In addition to it being a necessary condition for the maintenance of this type of plasma discharge, the utilization of reduced pressure avoids the risk of explosion, safely contains process materials, and removes volatile components from the deposited composite coating. The in-situ removal of unadhered material during the process has a number of additional benefits that include the reduced risk of contamination and poisoning (e.g. to production personnel, equipment, and product users), and more stable and predictable surface properties (such as greater adhesion to subsequently bonded materials).

If necessary after treatment, the coated substrate may be retained within the evacuated apparatus for an extended period of time sufficient to remove a required quantity of loosely adhered material such as unreacted precursor or unbonded oligomers.

In a yet further aspect of the invention, there is provided a method for depositing a composite coating onto a substrate, the method comprising the introduction of an atomized solid/liquid slurry into a continuous non-equilibrium sub-atmosheric pressure plasma.

In a further aspect of the invention, there is provided a method for applying a coating to a substrate. The method includes the steps of introducing a coating material into a non-equilibrium sub-atmospheric pressure plasma prior to application to the substrate.

The resulting composite coating formed exhibits enhanced surface properties, safety, and environmental stability as a result of their production at sub-atmospheric pressures.

### BRIEF DESCRIPTION OF THE DRAWINGS

The invention is now described with reference to the accompanying drawings; wherein:

FIGS. 1a and b illustrate two embodiments in schematic fashion of the method of the invention; and

FIG. 2 illustrates an apparatus that uses a continuous-wave radio frequency (RF) plasma to effect deposition of atomized, solid particle containing, coating forming materials.

### DETAILED DESCRIPTION OF THE INVENTION

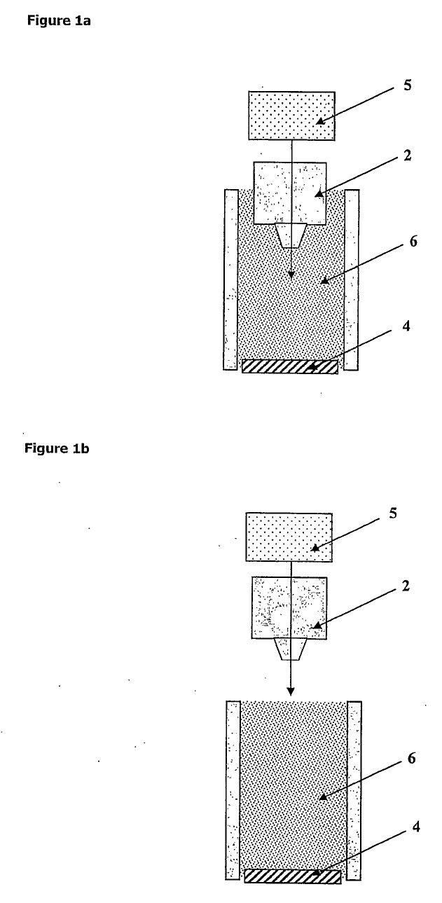

With reference to FIGS. 1a and b there are shown an atomizer 2, substrate 4, a vessel containing a solid/liquid slurry of coating forming material 5, and exciting medium 6 in the form of a sub atmospheric plasma 6.

The sub-atmospheric pressure plasma 6 shall, in its preferred embodiments, constitute a plasma discharge ignited surrounding (FIG. 1a), or in a region downstream of (FIG. 1b), the source 2 of atomized coating forming material. Suitable plasmas for use in the method of the invention include non-equilibrium plasmas such as those generated by audiofrequencies, radiofrequencies (RF), microwaves or direct current.

Of special utility are low-pressure RF plasmas wherein the gas pressure is 0.01 to 10 mbar. However, any type of plasma capable of operation at a pressure sufficiently low to provides the benefits previously cited may be deemed suitable. Conventional means for generating a sub-atmospheric pressure discharge include, but are not limited to, low-pressure plasma jet, sub-atmospheric pressure microwave glow discharge, sub-atmospheric pressure capacitively coupled discharge, and subatmospheric pressure glow discharge.

Precise conditions under which plasma deposition can take place in an effective manner will vary depending upon factors such as the nature of the atomized coating forming material or the substrate and can be determined using routine methods. In general, however, coating is effected by applying an alternating voltage of average powers of, for example, 0.1 W to 10,000 W.

It is envisaged that multi-layer or gradated coatings may be produced by a variety of means: such as varying the characteristics of the atomization source; varying the introduction of reactive, additive species to the sub-atmospheric pressure plasma (e.g. intermittently adding oxygen); changing the location of substrate during coating; varying the intensity of the sub-atmospheric pressure plasma; changing the nature of the subatmospheric pressure plasma (e.g. from radio frequency to microwave frequency); changing the composition of the coating forming material (e.g. varying the concentration of solid particles within the coating forming slurry), and performing multiple treatments (with one or more apparatuses).

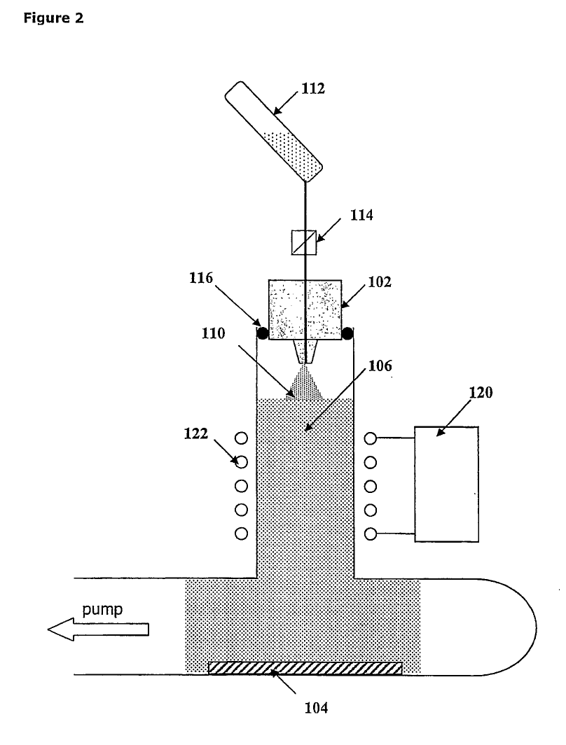

The invention will now be particularly described by way of an example with reference to FIG. 2 which shows a diagram of an apparatus that uses a low-pressure radiofrequency (RF) plasma 106 to effect deposition of atomized coating forming materials 110 dispensed from atomizer 102 onto substrate 104.

The next example is intended to illustrate the present invention but is not intended to limit the same.

### Deposition of Hydrophobic Composite Films

A coating forming material comprising a solid/liquid slurry of 1H, 1H, 2H, 2H perfluorooctylacrylate and silicon dioxide nanoparticles (DeGussa) is placed into a monomer tube 112 and purified using repeated freeze-pump-thaw cycles. Coating deposition is performed in an apparatus consisting of an ultrasonic atomization nozzle 102 interfaced to a means of generating an inductively-coupled radiofrequency plasma 106. The monomer tube is connected to the ultrasonic nozzle by way of a metering valve 114. The ultrasonic nozzle is connected to the plasma-reactor by way of nitrile “O-rings” 116.

A thermocouple pressure gauge is connected to the inductively coupled plasma chamber.

An inlet valve is connected to the external, ambient air supply and another valve connects the coating chamber to an Edwards E2M2 two stage rotary pump by way of a liquid nitrogen cold trap. All connections are grease free. An L-C matching unit and a power meter are used to couple the output from a 13.56 MHz RF generator 120 to the copper coils 122 that generate the low-pressure plasma excitation volume 106. This arrangement minimizes the standing wave ratio (SWR) of the power transmitted from the RF generator to the partially ionized plasma excitation volume.

Prior to the deposition of the coating forming material the ultrasonic nozzle, metering valve and related fittings are rinsed with propan-2-ol and air-dried. The monomer tube, ultrasonic nozzle, metering valve and related fittings are then attached to the plasma reactor which has been previously cleaned with a continuous RF oxygen plasma. Next the substrates (e.g. silicon wafers) are placed within the plasma chamber and the apparatus evacuated to base pressure (2×10-3 Torr).

The metering valve is then opened until the liquid/solid slurry flows into the ultrasonic nozzle at a rate of 0.03 ml min-1. Switching on the ultrasonic generator (with a broadband power of 3.0 W) initiates atomization of the coating forming material, resulting in an increase in the chamber pressure to approximately 0.2 Torr. The plasma is then ignited.

Typically a 0-10 minute deposition duration is used, and found to be sufficient to give complete coverage of the substrates. After this the metering valve 114 is closed, the RF power generator 120 switched off, and the apparatus evacuated in order to remove sufficient unadhered material before finally venting to atmospheric pressure via the air inlet valve.

A spectrophotometer (Aquila Instruments nkd-6000) is used to determine the thickness of the coatings. Contact angle measurements are made with a video capture apparatus (AST Products VCA2500XE) using sessile 2 μL droplets of deionized water and n-decane as probe liquids for hydrophobicity and oleophobicity respectively. Transmission Electron Microscopy (TEM) of the cleaved edge of a sample, scanning X-ray Photoelectron Spectroscopy (XPS), scanning Auger Spectroscopy or Energy Dispersive Xray Analysis (EDAX) confirm the presence of silicon dioxide nanoparticles throughout the continuous matrix of polymerized 1H, 1H, 2H, 2H perfluorooctylacrylate.

The present invention therefore provides the use of an atomizer to inject a coating material such as a liquid/solid particulate slurry into a sub-atmospheric pressure to generate a high flux of excited coating forming material that permits the rapid deposition, even from involatile precursors, of the composite coating. The use of plasma discharges operated at reduced pressures results in the more efficient consumption of process precursors and gases, a reduced risk of explosion compared to atmospheric pressure processes (1 atmosphere=1.01×105 Nm-2), and facilitates the removal of volatile components from the deposited composite coatings prior to their use. The removal of unadhered material has a number of important benefits that include, but are not limited to, a reduced risk of contaminating production personnel, product users and the environment, and more stable and predictable surface properties such as greater adhesion to subsequently bonded materials.

1. A method for depositing a coating onto a substrate, said method comprising the following steps:
the introduction of a coating material to form the coating on at least part of the substrate; and
wherein the coating material is introduced in the form of an atomized solid/liquid slurry into a sub-atmospheric pressure plasma prior to and/or when contacting the substrate.

2. The method according to claim 1 wherein atomized droplets of the coating material create reactive species in the form of ions, radicals and metastable molecules, or any combination thereof.

3. The method according to claim 2 wherein the atomized droplets of the coating material are subsequently deposited onto the substrate and form a coating containing solid particles dispersed within a substantially continuous matrix.

4. The method according to claim 1 wherein excitation of the coating material occurs after its absorption onto the substrate.

5. The method according to claim 1 wherein liquid fraction of the coating material contains one or more components that, upon atomization and exposure to the sub-atmospheric pressure plasma, can be transformed into a continuous phase of the coating.

6. The method according to claim 1 wherein the coating which is formed is a composite coating.

7. The method according to claim 1 wherein the coating material used is an organic monomer which, after atomization and excitation, forms a continuous polymer matrix.

8. The method according to claim 1 wherein the coating material used includes any, or any combination, of liquid organo-metallic, organo-silicon and/or inorganic compounds.

9. The method according to claim 1 wherein the solid content of the coating material includes particles with diameters in the nm or mm range.

10. The method according to claim 9 wherein said solid content includes any, or any combination, of organic, inorganic, organo-metallic, metallic, organo-silicon and/or bioactive particles.

11. The method according to claim 9 wherein the particles can be dispersed throughout a continuous phase of the composite coating and include any, or any combination, of titanium dioxide, manganese oxide, silver, carbon black, carbon fibers, graphite and/or microfine ptfe, palladium/gold and/or organic light emitting molecules.

12. The method according to claim 1 wherein solid particle components of the coating material are surface modified prior to inclusion in the liquid/solid coating forming slurry.

13. The method according to claim 12 wherein the solid particles are the subject of a treatment to enhance dispersion within the coating material.

14. The method according to claim 13 wherein the solid particles are surface modified to include C16-silane modified silica.

15. The method according to claim 12 wherein prior to inclusion in the coating material, the particles are subjected to a surface modification pre-treatment.

16. The method according to claim 15 wherein the particles include methacrylsilane modified silica nano-particles.

17. The method according to claim 1 wherein an atomizer is used to enable rapid deposition rates of the coating material to be achieved.

18. The method according to claim 17 wherein the atomizer is an ultrasonic nozzle.

19. The method according to claim 17 wherein the atomizer is a nebulizer used in conjunction with a carrier gas.

20. The method according to claim 17 wherein the coating material is conveyed from a reservoir to the atomizer by virtue of gravitational potential.

21. The method according to claim 17 wherein the coating material is conveyed from a reservoir to the atomizer by pressure differential between the reservoir and a chamber in which the atomizer is positioned and in which the sub-atmospheric pressure plasma is generated.

22. The method according to claim 21 wherein the pressure differential between the chamber and the slurry reservoir is augmented by the application of a positive pressure of an inert gas within the reservoir at a pressure above the pressure level of the coating material.

23 The method according to claim 20 wherein the reservoir is in the form of a syringe.

24. The method according to claim 17 wherein more than one atomizer can be used to supply coating material into the sub-atmospheric pressure plasma.

25. The method according to claim 24 wherein the more than one atomizing nozzle are provided in an array distributed transversely to a direction of movement of the substrate to be coated.

26. The method according to claim 1 wherein at least one material in addition to the atomized liquid/solid slurry are included within the coating process.

27. The method according to claim 26 wherein the at least one material is inert and acts as a buffer to maintain a required process pressure and/or carry the atomized coating material into an appropriate region of the coating apparatus.

28. The method according to claim 26 wherein the at least one material can be used to modify and/or be incorporated into the coating material and/or the resulting coating applied to the substrate.

29. The method according to claim 26 wherein the at least one additional material is introduced into the coating chamber in a pulsed manner.

30. The method according to claim 1 wherein non-equilibrium sub-atmospheric pressure plasma is generated by an alternating current voltage.

31. The method according to claim 1 wherein the sub-atmospheric pressure plasma is produced by selection from the group consisting of frequency, radio frequency and microwave frequency.

32. The method according to claim 31 wherein the sub-atmospheric pressure plasma is produced by a radio frequency glow discharge.

33. The method according to claim 32 wherein a low pressure radio frequency glow discharge is operated at pressures between 0.01 and 10 mbar.

34. The method according to claim 1 wherein the sub-atmospheric pressure plasma is produced by direct current voltage.

35. The method according to claim 1 wherein the substrate to which the coating material is applied is located substantially inside an exciting medium during deposition of the coating material.

36. The method according to claim 1 wherein the substrate introduction of the coating material and generation of the sub-atmospheric pressure plasma are located within a coating chamber.

37. The method according to claim 1 wherein the coating formed on the substrate is post treated by exposure to further exciting media.

38. The method according to claim 1 wherein the substrate is pre-treated prior to coating by exposure to exciting media prior to the deposition of the coating material.

39. The method according to claim 1 wherein the apparatus in the vicinity of the sub-atmospheric pressure plasma region is heated to prevent condensation of coating material onto the chamber walls.

40. The method according to claim 1 wherein the substrate comprises any or any combination of metals, glass, semi-conductor, ceramic, polymer, woven or non-woven fibers, natural fibers, synthetic fibers, cellulosic material and powder.

41. The method according to clam 1 wherein the coating material includes any or any combination of a mixture of organic, organo-silicone, organo-metallic, or inorganic liquid coating precursor with a suspension of largely insoluble inorganic, organo-silicon, organo-metallic, inorganic or bio-active solid particles.

42. The method according to claim 1 wherein the coating formed is selected to improve any or any combination of hydrophobic and/or oliophobic properties, adhesive, gas barrier, wear resistance, moisture barrier, release, electrical and thermal conductivity, electrical and thermal reflectance, energy production and storage, filtration, magnetic, dielectric, bioactive, optical or tribiological properties of the substrate.

43. The method according to claim 1 wherein after deposition of a composite film the coated substrate is subject to subsequent derivitization.

44. The method according to claim 1 wherein a multi-layer composite coating is formed on the substrate and the substrate is repeatedly exposed to activated coating material within a sub-atmospheric pressure plasma.

45. The method according to claim 44 wherein the coating material composition is changed during the coating formation.

46. The method according to claim 44 wherein the nature of the sub-atmospheric pressure plasma is changed during the coating formation procedure.

47. The method according to claim 1 wherein the substrate is mounted on a reel to reel drive apparatus and coated continuously.

48. The method according to claim 1 wherein the plasma is a non-equilibrium, continuous sub-atmospheric pressure plasma.

49. The method according to claim 21 wherein the reservoir is in the form of a syringe.

50. The method according to claim 22 wherein the reservoir is in the form of a syringe.

51. The method according to claim 27 wherein the at least one material can be used to modify and/or be incorporated into the coating material and/or the resulting coating applied to the substrate.

52. A method for forming a coating on a substrate, said method comprising the steps of:
atomizing and nebulizing a coating material and introducing it into a sub-atmospheric pressure plasma to facilitate the formation of activated precursor species to the coating within atomized droplets and/or upon their absorption onto the substrate.

53. The method according to claim 52 wherein the activated precursor species form a coating upon the substrate that contain solid particles within a matrix formed by the deposition of an excited liquid component of the coating material.

54. The method according to claim 52 wherein the coating material is a liquid/solid slurry which is atomized by an ultrasonic nozzle into the sub-atmospheric pressure plasma region.

55. The method according to claim 54 wherein the sub-atmospheric pressure plasma contains the atomized coating forming slurry material in the absence of other materials.

56. A method for applying a coating to a substrate, said method comprising the steps of:
introducing a coating material into a non-equilibrium sub-atmospheric pressure plasma prior to application of the coating material to the substrate.

57. A method for depositing a composite coating onto a substrate, said method comprising the step of introduction of an atomized solid/liquid slurry into a continuous non-equilibrium sub-atmospheric pressure plasma.

58. Apparatus for the application for a composite coating to a substrate, said apparatus comprising:
a vacuum chamber;
atomizing means for introducing an atomized coating material in a slurry form into the chamber;
means for creating a sub-atmospheric pressure plasma within the chamber; and
a means for introducing and holding at least one substrate to be coated in the chamber.

59. The apparatus according to claim 58 wherein the atomizing means directs the atomized coating forming material so that it passes through the sub-atmospheric pressure plasma prior to reaching the substrate.
